(19) United States
(12) Patent Application Publication
(10) Pub. No.: US 2002/0079232 A1
(43) Pub. Date: Jun. 27, 2002

(54) Seed layer deposition

(75) Inventor: James G. Shelnut, Northboro, MA (US)

Correspondence Address: S. Matthew Cairns, c/o EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 10/057,624

(22) Filed: Oct. 25, 2001

Related U.S. Application Data
(60) Provisional application No. 60/243,084, filed on Oct. 25, 2000.

(51) Int. Cl. C25D 3/00; H01L 21/445; C25D 3/38; C25D 3/30

(52) U.S. Cl. 205/238; 205/239; 205/252; 205/261; 205/271; 205/291; 205/299; 205/300; 205/123; 428/411.1

(57) ABSTRACT

Disclosed are methods for depositing a conductive layer on a substrate having a barrier layer and/or a dielectric layer. Such methods are particularly suitable for depositing an electroplated copper layer on a substrate having small apertures, and preferably very small apertures.

### BACKGROUND OF THE INVENTION

The present invention relates generally to the to the field of seed layers for subsequent metallization. In particular, this invention relates to methods for depositing seed layers prior to metallization.

The trend toward smaller microelectronic devices, such as those with sub-micron geometries, has resulted in devices with multiple metallization layers to handle the higher densities. One common metal used for forming metal lines, also referred to as wiring, on a semiconductor wafer is aluminum. Aluminum has the advantage of being relatively inexpensive, having low resistivity, and being relatively easy to etch. Aluminum has also been used to form interconnections in vias to connect the different metal layers. However, as the size of via/contact holes shrinks to the sub-micron region, a step coverage problem appears which in turn can cause reliability problems when using aluminum to form the interconnections between the different metal layers. Such poor step coverage results in high current density and enhances electromigration.

One approach to providing improved interconnection paths in the vias is to form completely filled plugs by using metals such as tungsten while using aluminum for the metal layers. However, tungsten processes are expensive and complicated, tungsten has high resistivity, and tungsten plugs are susceptible to voids and form poor interfaces with the wiring layers.

Copper has been proposed as a replacement material for interconnect metallizations. Copper has the advantages of improved electrical properties as compared to tungsten and better electromigration property and lower resistivity than aluminum. The drawbacks to copper are that it is more difficult to etch as compared to aluminum and tungsten and it has a tendency to migrate into the dielectric layer, such as silicon dioxide. To prevent such migration, a barrier layer, such as titanium nitride, tantalum nitride and the like, must be used prior to the depositing of a copper layer.

Typical techniques for applying a metal layer, such as electrochemical deposition, are only suitable for applying copper to an electrically conductive layer. Thus, an underlying conductive seed layer, is generally applied to the substrate prior to electrochemically depositing copper. Such seed layers are typically metallic and are applied by a variety of methods, such as physical vapor deposition (“PVD”) and chemical vapor deposition (“CVD”). Typically, metal seed layers are thin in comparison to other layers, such as from 50 to 1500 angstroms thick. Such metal seed layers, particularly copper seed layers, may suffer from problems such as metal oxide both on the surface of the seed layer and in the bulk of the layer as well as discontinuities in the layer.

Discontinuities or void areas in the seed layer where coverage of the metal, such as copper, is incomplete or lacking. Such discontinuities can arise from insufficient blanket deposition of the metal layer, such as depositing the metal in a line of sight fashion. In order for a complete metal layer to be electrochemically deposited on such a seed layer, the discontinuities must be filled in prior to or during the deposition of the final metal layer, or else voids in the final metal layer may occur. For example, PCT patent application number WO 99/47731 (Chen) discloses a method of providing a seed layer by first vapor depositing an ultra-thin seed layer followed by electrochemically enhancing the ultra-thin seed layer to form final a seed layer. According to this patent application, such a two step process provides a seed layer having reduced discontinuities, i.e. areas in the seed layer where coverage of the seed layer is incomplete or lacking.

Physical or chemical vapor deposition methods are complicated and difficult to control. Further, PVD methods tend to deposit metal in a line of sight fashion.

There is a need for methods of enhancing seed layers that will subsequently be plated with metals for use electronic devices, particularly in devices having very small geometries such as 0.5 micron and below. There is also a need for methods of providing substantially continuous seed layers.

### SUMMARY OF THE INVENTION

It has been surprisingly found that a substantially continuous conductive layer can be deposited onto the surface of a non-conductive layer such as that present in electronic device constructions, and in particular back-end-of-line constructions. The present invention provides substantially continuous conductive layers that conform to the surface geometries of the substrate, particularly on substrates having apertures of ≦1 μm.

In one aspect, the present invention provides a method of depositing a seed layer including the step of disposing on a substrate having a non-conductive layer and apertures of ≦1 μm a layer including one or more conductive polymers.

In second aspect, the present invention provides a method for depositing a metal layer on a substrate including the steps of: disposing on a substrate having a non-conductive layer and apertures of ≦1 μm a layer including one or more conductive polymers; contacting the substrate with a metal electroplating bath; and subjecting the substrate to a current density for a period of time sufficient to deposit a metal layer on the conductive layer.

In a third aspect, the present invention provides a method for manufacturing an electronic device including the steps of: disposing on an electronic device substrate having a non-conductive layer and apertures of ≦1 μm a layer including one or more conductive polymers; contacting the substrate with a metal electroplating bath; and subjecting the substrate to a current density for a period of time sufficient to deposit a metal layer on the conductive layer.

In a fourth aspect, the present invention provides a method of enhancing a seed layer including the step of: contacting a substrate having a discontinuous seed layer with one or more conductive polymers to provide a substantially continuous seed layer.

In a fifth aspect, the present invention provides an electronic device substrate having apertures of ≦1 μm and having a substantially continuous seed layer including one or more conductive polymers.

### DETAILED DESCRIPTION OF THE INVENTION

The following abbreviations shall have the following meanings unless the text clearly indicates otherwise: nm=nanometers; μm=micron=micrometer;° C.=degrees Centigrade; g/L=grams per liter; and ppm=parts per million.

As used throughout the specification, “feature” refers to the geometries on a substrate, such as, but not limited to, trenches and vias. “Apertures” refer to recessed features, such as vias and trenches. The term “small features” refers to features that are one micron or smaller in size. “Very small features” refers to features that are one-half micron or smaller in size. Likewise, “small apertures” refer to apertures that are one micron or smaller (<1 μm) in size and “very small apertures” refer to apertures that are one-half micron or smaller (<0.5 μm) in size. As used throughout this specification, the term “plating” refers to metal electroplating, unless the context clearly indicates otherwise. “Deposition” and “plating” are used interchangeably throughout this specification. “Halo” refers to fluoro, chloro, bromo, and iodo. Likewise, “halide” refers to fluoride, chloride, bromide and iodide. “Alkyl” includes straight chain, branched and cyclic alkyl groups.

All percentages and ratios are by weight unless otherwise indicated. All ranges are inclusive and combinable.

The present invention provides a method for depositing a seed layer including the step of disposing on a substrate having a non-conductive layer and apertures of ≦1 μm a layer including one or more conductive polymers. Suitable non-conductive layers include dielectric layers and barrier layers, such as those used in the manufacture of integrated circuits. Typical dielectric materials include silicon dioxide, fluorinated silicon dioxide, organopolysilica materials such as those prepared from alkyl and/or arylsilsesquioxanes; and organic dielectric materials. Suitable barrier layers include, but are not limited to, tantalum, tantalum nitride, titanium, titanium nitride, tungsten, tungsten nitride, molybdenum, molybdenum nitride, cobalt, cobalt nitride, and the like. Any material may be a barrier layer if it acts a barrier layer to migration of conductive metals, particularly as a barrier to the electromigration of copper.

The present invention is suitable for depositing a conductive layer on a variety of substrates, particularly those used in the manufacture of electronic devices. Suitable substrates are any that contain a suitable layer for subsequent deposition of conductive species. Preferably, the suitable layer is a non-conductive layer. As used herein “non-conductive layers” include substantially non-conductive layers. Such non-conductive layers include any layer that is not sufficiently conductive to allow for direct electrodeposition of a metal directly on such layer and any layer that does not allow for effective electrodeposition of a metal. Particularly substrates are wafers used in the manufacture of integrated circuits and semiconductors, printed wiring board inner layers and outer layers, flexible circuits and the like. It is preferred that the substrate is a wafer. Exemplary substrates include, but are not limited to, those containing one or more apertures having a size of ≦1 μm, particularly ≦0.5 μm, and more particularly ≦0.18 μm.

A wide variety of conductive polymers may be used in the current invention. Suitable conductive polymers include organic and inorganic polymers and include but are not limited to, polyacetylene, polyaniline, polypyrrole, polythiophenes, graphite and the like. Such organic polymers may be unsubstituted or substituted. By “substituted” is meant that one or more of the hydrogens in the polymer is replaced by one or more substituent groups including, but not limited to, halo, (C₁-C₁₀)alkyl, (C₁-C₆)alkoxy, aryl, aryloxy, amino, (C₁-C₄)alkylamino, di(C₁-C₄)alkylamino, tri(C₁-C₄)alkylammonium, (C₁-C₁₀)alkylthio, arylthio, (C₁-C₁₀)alkylsulfonium, arylsulfonium, and the like. In general, such organic conductive polymers are prepared from their monomers, such as acetylene, aniline, pyrrole, or thiophene. Suitable substituted organic polymers may be prepared by appropriate surface modification of the polymers or by the preparation of such polymers using appropriately substituted monomers. It will be appreciated by those skilled in the art that such organic polymers may be homopolymers or copolymers. Suitable copolymers include any conductive polymers including as polymerized units one or more selected from acetylene, aniline, pyrrole, or thiophene; and one or more other monomers. As used herein, “monomers” refer to any compound that can be polymerized, preferably monomers contain one or more of double or triple bonds. Methods of preparing such organic conductive polymers are well known in the literature. The conductive polymers are generally, do not necessarily have to be, supplied in a solvent either water or organic solvent. Such conductive polymer and solvent compositions may be in the form of solutions, dispersions, slurries and the like.

The substrate having a non-conductive layer is typically contacted with the one or more conductive polymers in a variety of ways, such as by immersion, spraying, spin coating, flood coating, dip coating and the like. After contact with the one or more conductive polymers, the substrate may optionally be rinsed and/or dried prior to subsequent processing. At this stage, a substrate having a substantially continuous conductive layer, and preferably a continuous conductive layer, is provided.

In an alternative embodiment, a substrate containing a prior deposited seed layer (conductive layer) containing discontinuities may be contacted with the one or more conductive polymers to provide an enhanced seed layer. Thus, the present invention is also suitable for enhancing a discontinuous metal seed layer on a substrate. By “enhancing” a discontinuous seed layer is meant that the seed layer is repaired or extended to substantially fill in, and preferably fill in, such discontinuities or areas devoid of seed layer. Thus, the present invention further provides a method of enhancing a seed layer including the steps of: contacting a substrate having a discontinuous seed layer one or more conductive polymers to provide a substantially continuous seed layer.

The present invention may be used to enhance seed layers deposited by CVD or PVD. Preferably, such seed layers are copper or copper alloy. It is further preferred that such seed layers are disposed on wafers used in the manufacture of integrated circuits.

An advantage is that the resulting seed layer is substantially continuous and preferably continuous. That is, seed layers enhanced by the current method cover >95% of the surface area of the substrate, preferably >98%, and more preferably >99%. Such seed layers are also uniform due to conductive polymer deposition being conformal.

After contact with the one or more conductive polymers, the substrate is placed into an electroplating bath and subjected to a current density for a period of time to initiate plating of a metal layer on the conductive layer until the desired plating thickness has been reached. A wide variety of metal electroplating baths may be used including, but not limited to, one or more of copper, nickel, aluminum, tin, lead, tungsten and the like. Thus, such electroplating baths may deposit a pure metal or an alloy.

For purposes of illustration, the present invention will be described with respect to electrodeposition of copper. Copper electroplating baths typically contain one or more sources of copper ions and an electrolyte. A variety of copper salts may be employed in copper electroplating solutions as sources of copper ions. Suitable copper salts include, but are not limited to, copper sulfates, copper acetates, copper fluoroborate, copper gluconate, copper formate, copper alkanesulfonates, copper arylsulfonates, copper sulfamates, copper sulfonates, and cupric nitrates. Copper sulfate pentahydrate is particularly suitable. A copper salt may be suitably present in a relatively wide concentration range in these electroplating solutions. Preferably, a copper salt will be employed at a concentration of from about 1 to about 300 g/L of plating solution, more preferably at a concentration of from about 10 to about 225 g/L, still more preferably at a concentration of from about 25 to about 175 g/L. The copper plating bath may also contain amounts of other alloying elements, such as, but not limited to, tin, zinc, and the like. Thus, the copper electroplating baths may also deposit a copper alloy.

Suitable copper electroplating baths preferably employ an acidic electrolyte, which may include one or more acids. Suitable acids are inorganic or organic. Useful inorganic acids include, but are not limited to, sulfuric acid, phosphoric acid, nitric acid, hydrogen halide acids, sulfamic acid, fluoroboric acid and the like. Suitable organic acids include, but are not limited to, alkylsulfonic acids such as methanesulfonic acid, aryl sulfonic acids such as phenolsulfonic acid and tolylsulfonic acid, carboxylic acids such as formic acid, acetic acid and propionic acid, halogenated acids such as trifluoromethylsulfonic acid and haloacetic acid, and the like. Particularly suitable organic acids include (C₁-C₁₀)alkylsulfonic acids. Particularly suitable combinations of acids include one or more inorganic acids with one or more organic acids or a mixture of two or more organic acids. When two or more acids are used in the electrolyte, they may be used in any ratio from 99:1 to 1:99, preferably from 90:10 to 10:90, and more preferably from 80:20 to 20:80.

The total amount of added acid used in the present electroplating baths may be from about 0 to about 350 g/L, and preferably from 1 to 225 g/L. It will be appreciated by those skilled in the art that by using a metal sulfate as the metal ion source, an acidic electrolyte can be obtained without any added acid. Thus, in one embodiment, copper electroplating solutions may be free of added acid.

Such electroplating baths may optionally contain one or more additives, such as halides, accelerators or brighteners, suppressors, levelers, grain refiners, wetting agents, surfactants and the like. Preferred copper electroplating baths are those containing >1.5 mg/L of one or more brightener compounds. The amounts of such additives are well within the ability of those skilled in the art. A particularly suitable electroplating bath is ULTRAFILL™2001 EP copper deposition chemistries, available from Shipley Company (Marlborough, Massachusetts).

The substantially continuous seed layers of the present invention are typically plated or metallized by contacting the seed layer with the above described electroplating bath. The seed layer is typically contacted with the electroplating solution for a period of time and at a current density sufficient to deposit the desired thickness of metal on the seed layer. Copper plating baths are preferably employed at a wide range of temperatures from below room temperature to above room temperature, e.g. up to 65° C. and greater. The plating bath is preferably agitated during use such as by air sparger, work piece agitation, impingement or other suitable method. Plating is preferably conducted at a current ranging from 1 to 40 ASF depending upon substrate characteristics. Plating time may range from about 2 minutes to 1 hour or more, depending on the difficulty of the work piece.

Thus, the present invention provides a method for depositing a metal layer on a substrate including the steps of: disposing on a substrate having a non-conductive layer and apertures of ≦1 μm a layer including one or more conductive polymers; contacting the substrate with a metal electroplating bath; and subjecting the substrate to a current density for a period of time sufficient to deposit a metal layer on the conductive layer.

The seed layers of the present invention may be deposited on a wide variety of substrates, as discussed above. The methods of the invention are particularly useful to provide seed layers for subsequent electroless or electrolytic plating of difficult work pieces, such as circuit board substrates with small diameter, high aspect ratio microvias and other apertures. The methods of the invention are also particularly useful for depositing seed layers on integrated circuit devices, such as formed semiconductor devices and the like. The methods of the present invention are particularly suitable for providing substantially continuous seed layers on substrates having high aspect ratio microvias and trenches, such as those having aspect rations of 4:1 or greater.

As discussed above, aspect ratios of at least 4:1, having diameters of about 200 nm or smaller can be effectively copper plated with no defects (e.g. no voids or inclusions by ion beam examination) on the substantially continuous seed layers of the invention. Seed layers on substrates including apertures with diameters below 150 nm, or even below about 100 nm, and aspect ratios of 5:1, 6:1, 7:1, 10:1 or greater, and even up to about 15:1 or greater can be deposited or effectively enhanced using the present invention. The present invention is particularly suitable for depositing and repairing seed layers on substrates having 0.18 μm and smaller apertures.

In one embodiment, the present invention provides an electronic device substrate having apertures of ≦1 μm and including a substantially continuous seed layer comprising one or more conductive polymers. Preferably, such an electronic device substrate is a wafer used in integrated circuit manufacture.

Thus, in another embodiment, the present invention provides a method for manufacturing an electronic device including the steps of: disposing on an electronic device substrate having a non-conductive layer and apertures of ≦1 μm a layer including one or more conductive polymers; contacting the substrate with a metal electroplating bath; and subjecting the substrate to a current density for a period of time sufficient to deposit a metal layer on the conductive layer.

After metallization, i.e. filling of the apertures, the substrate, in the case of a wafer, is preferably subjected to chemical-mechanical planarization (“CMP”). A CMP procedure can be conducted in accordance with the invention as follows.

The wafer is mounted in a wafer carrier which urges the wafer against the surface of a moving polishing pad. The polishing pad can be a conventional smooth polishing pad or a grooved polishing pad. Suitable grooved polishing pads are those available from Rodel, Inc. (Newark, Del.). The polishing pad can be located on a conventional platen which can rotate the polishing pad. The polishing pad can be held on the platen by a holding means such as, but not limited to, an adhesive, such as, two faced tape having adhesive on both sides.

A polishing solution or slurry is fed onto the polishing pad. The wafer carrier can be at different positions on the polishing pad. The wafer can be held in position by any suitable holding means such as, but is not limited to, a wafer holder, vacuum or liquid tensioning such as, but not limited to a fluid such as, but not limited to water. If the holding means is by vacuum then there is preferably a hollow shaft which is connected to the wafer carrier. Additionally, the hollow shaft could be used to regulate gas pressure, such as, but not limited to air or an inert gas or use a vacuum to initially-hold the wafer. The gas or vacuum would flow from the hollow shaft to the carrier. The gas can urge the wafer against the polishing pad for the desired contour. The vacuum can initially hold the wafer into position in the wafer carrier. Once the wafer is located on top of the polishing pad the vacuum can be disengaged and the gas pressure can be engaged to thrust the wafer against the polishing pad. The excess or unwanted copper is then removed. The platen and wafer carrier can be independently rotatable. Therefore, it is possible to rotate the wafer in the same direction as the polishing pad at the same or different speed or rotate the wafer in the opposite direction as the polishing pad.

Thus, the present invention provides a method for removing excess material from a semiconductor wafer containing one or more apertures of ≦1 μm by using a chemical mechanical planarization process which includes contacting the semiconductor wafer with a rotating polishing pad thereby removing the excess material from the semiconductor wafer; wherein the apertures contain a seed layer deposit obtained from disposing on an electronic device substrate having a non-conductive layer and apertures of ≦1 μm a bath layer including one or more conductive polymers.

What is claimed is:

1. A method for depositing a method of depositing a seed layer comprising the step of disposing on a substrate having a non-conductive layer and apertures of ≦1 μm a layer comprising one or more conductive polymers.

2. The method of claim 1 wherein the non-conductive layer is selected from a dielectric layer or a barrier layer.

3. The method of claim 2 wherein the dielectric layer comprises one or more of silicon dioxide, fluorinated silicon dioxide, organopolysilica materials, or organic dielectric materials.

4. The method of claim 2 wherein the barrier layer is selected from tantalum, tantalum nitride, titanium, titanium nitride, tungsten, tungsten nitride, molybdenum, molybdenum nitride, cobalt or cobalt nitride.

5. The method of claim 1 wherein the one or more conductive polymers are selected from polyaniline, polyacetylene, polypyrrole, polythiophene or graphite.

6. The method of claim 4 wherein the one or more of polyaniline, polyacetylene, polypyrrole or polythiophene are substituted.

7. The method of claim 1 wherein the apertures are less than or equal to 5 μm.

8. A method for depositing a metal layer on a substrate comprising the steps of: disposing on a substrate having a non-conductive layer and apertures of ≦1 μm a layer comprising one or more conductive polymers; contacting the substrate with a metal electroplating bath; and subjecting the substrate to a current density for a period of time sufficient to deposit a metal layer on the conductive layer.

9. The method of claim 8 wherein the non-conductive layer is selected from a dielectric layer or a barrier layer.

10. The method of claim 9 wherein the dielectric layer comprises one or more of silicon dioxide, fluorinated silicon dioxide, organopolysilica materials, or organic dielectric materials.

11. The method of claim 9 wherein the barrier layer is selected from tantalum, tantalum nitride, titanium, titanium nitride, tungsten, tungsten nitride, molybdenum, molybdenum nitride, cobalt or cobalt nitride.

12. The method of claim 8 wherein the one or more conductive polymers are selected from polyaniline, polyacetylene, polypyrrole, polythiophene or graphite.

13. The method of claim 12 wherein the one or more of polyaniline, polyacetylene, polypyrrole or polythiophene are substituted.

14. The method of claim 8 wherein the apertures are less than or equal to 5 μm.

15. The method of claim 8 wherein the metal is selected from one or more of copper, nickel, aluminum, tin, lead or tungsten.

16. The method of claim 8 wherein the metal electroplating bath comprises an acidic electrolyte.

17. A method for manufacturing an electronic device comprising the steps of: disposing on an electronic device substrate having a non-conductive layer and apertures of ≦1 μm a layer comprising one or more conductive polymers; contacting the substrate with a metal electroplating bath; and subjecting the substrate to a current density for a period of time sufficient to deposit a metal layer on the conductive layer.

18. The method of claim 17 wherein the non-conductive layer is selected from a dielectric layer or a barrier layer.

19. The method of claim 18 wherein the dielectric layer comprises one or more of silicon dioxide, fluorinated silicon dioxide, organopolysilica materials, or organic dielectric materials.

20. The method of claim 18 wherein the barrier layer is selected from tantalum, tantalum nitride, titanium, titanium nitride, tungsten, tungsten nitride, molybdenum, molybdenum nitride, cobalt or cobalt nitride.

21. The method of claim 17 wherein the one or more conductive polymers are selected from polyaniline, polyacetylene, polypyrrole, polythiophene or graphite.

22. The method of claim 21 wherein the one or more of polyaniline, polyacetylene, polypyrrole or polythiophene are substituted.

23. The method of claim 17 wherein the apertures are less than or equal to 5 μm.

24. The method of claim 17 wherein the metal is selected from one or more of copper, nickel, aluminum, tin, lead or tungsten.

25. The method of claim 17 wherein the metal electroplating bath comprises an acidic electrolyte.

26. The method of claim 17 wherein the electronic device is an integrated circuit.

27. A method of enhancing a seed layer comprising the steps of: contacting a substrate having a discontinuous seed layer with one or more conductive polymers to provide a substantially continuous seed layer.

28. The method of claim 27 wherein the non-conductive layer is selected from a dielectric layer or a barrier layer.

29. The method of claim 28 wherein the dielectric layer comprises one or more of silicon dioxide, fluorinated silicon dioxide, organopolysilica materials, or organic dielectric materials.

30. The method of claim 28 wherein the barrier layer is selected from tantalum, tantalum nitride, titanium, titanium nitride, tungsten, tungsten nitride, molybdenum, molybdenum nitride, cobalt or cobalt nitride.

31. The method of claim 27 wherein the one or more conductive polymers are selected from polyaniline, polyacetylene, polypyrrole, polythiophene or graphite.

32. The method of claim 31 wherein the one or more of polyaniline, polyacetylene, polypyrrole or polythiophene are substituted.

33. The method of claim 27 wherein the apertures are less than or equal to 5 μm.

34. An electronic device substrate having apertures of ≦1 μm and having a substantially continuous seed layer comprising one or more conductive polymers.
